(19) United States
(12) Patent Application Publication
(10) Pub. No.: US 2006/0049505 A1
(43) Pub. Date: Mar. 9, 2006

(54) High density interconnect power and ground strap and method therefor

(75) Inventor: Chris Wyland, Livermore, CA (US)

Correspondence Address: PHILIPS ELECTRONICS NORTH AMERICA CORPORATION;INTELLECTUAL PROPERTY & STANDARDS, 1109 MCKAY DRIVE, M/S-41SJ, SAN JOSE, CA, 95131, US

(73) Assignee: Koninklijke Philips Electronics N.V., Eindhoven (NL)

(21) Appl. No.: 10/537,674

(22) PCT Filed: Dec. 4, 2003
(86) PCT No.: PCT/IB03/05616

§ 371 Date: Jun. 6, 2005

Related U.S. Application Data
(60) Provisional application No. 60/432,482, filed on Dec. 10, 2002.

(51) Int. Cl. H01L 23/48

(52) U.S. Cl. 257/690; 257/691

(57) ABSTRACT

One aspect of the present invention relates to reducing the impedance of the paths connecting the power or ground of a device and a BGA package. In a particular example implementation, impedance of the signal bond wires is controlled by placing a ground strap (130) at a predetermined distance from the signal bond wires (115). In a related example embodiment, a low impedance power or ground connection is made between a device die (140) and package in close proximity to wire bonds (115). An integrated circuit (140) includes a plurality of grounding pads, signal pads, power pads and a package for mounting the integrated circuit. The package (100) comprises a plurality of pad landings (110), a grounding ring (105) surrounding the integrated circuit (140); and a grounding strap (130) coupling the grounding ring (105) to the grounding pads (120) of the integrated circuit.

This application is related to concurrently filed application titled, “High Density Package Interconnect Wire Bond Strip Line and Method Therefor,” Attorney Docket Number US02 0512P and is herein incorporated by reference in its entirety.

The invention relates to the field of integrated circuit packaging, and particularly to the connecting of power or ground pads of a device to a package.

As integrated circuit technology improves to increase the density and complexity of devices that may be rendered in a given area of substrate, a significant challenge is posed to the packaging of these devices. In computer applications, for example, the width of the data bus has increased from 16, 32, 64, to 128 bits and beyond. During the movement of data in a system it is not uncommon for a bus to have simultaneously switching outputs (SSOs). The SSOs often result in the power and ground rails of the chip experiencing noise owing to the large transient currents present during the SSOs. If the noise is severe, the ground and power rails shift from their prescribed voltage causing unpredictable behavior in the chip.

In a BGA (Ball Grid Array) package, bond wires are often used to connect the device die to the ground on the package. In high pin count BGAs, a ground ring is commonly used. These bond wires are sometimes placed in close proximity to signal bond wires to control the impedance of signal bond wires by creating a coplanar waveguide structure.

U.S. Pat. Nos. 5,872,403 and 6,083,772 are directed to a structure and method of mounting a power semiconductor die on a substrate. They are directed in general, to power electronics and more specifically, to a low impedance heavy current conductor for a power device and method of manufacture therefor.

U.S. Pat. No. 6,319,775 B1 relates to a method of making an integrated circuit package, and in particular to a process for attaching a conductive strap to an integrated circuit die and a lead frame. This patent and the previous two cited are incorporated by reference in their entirety.

The present invention is advantageous in reducing the impedance of the paths connecting the power or ground of the device and the BGA package. Furthermore, the present invention can control the impedance of the signal bond wires by placing a ground strap at a predetermined distance from the signal bond wires.

In an example embodiment, there is an integrated circuit device comprising an integrated circuit having a plurality of grounding pads, signal pads, and power pads; and a package for mounting the integrated circuit. The package comprises a plurality of pad landings a grounding ring surrounding the integrated circuit and a grounding strap coupling the grounding ring to the grounding pads of the integrated circuit.

Additional advantages and novel features will be set forth in the description which follows, and in part may become apparent to those skilled in the art upon examination of the following, or may be learned by practice of the invention.

The invention is explained in further details, by way of examples, and with reference to the accompanying drawings wherein:

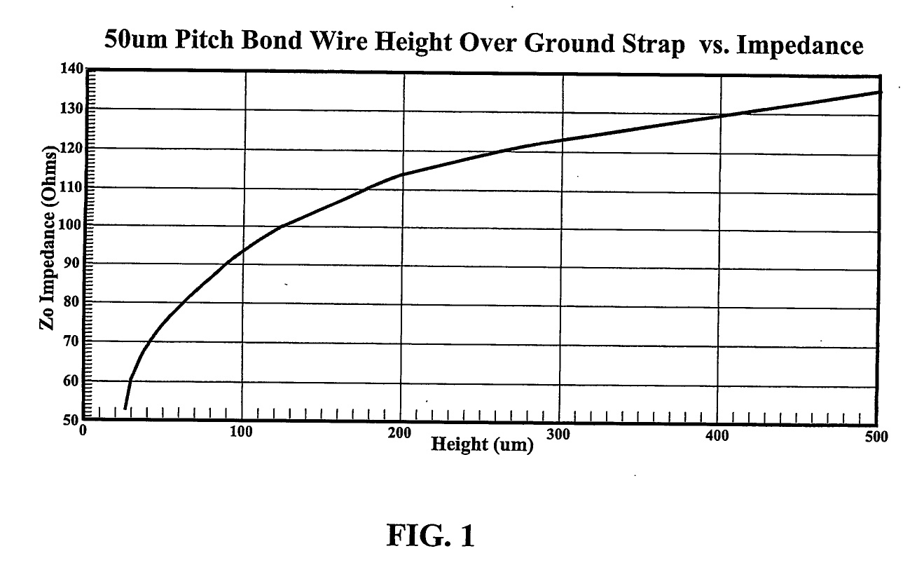

FIG. 1 is a plot of bond wire height over the ground strap v. impedance;

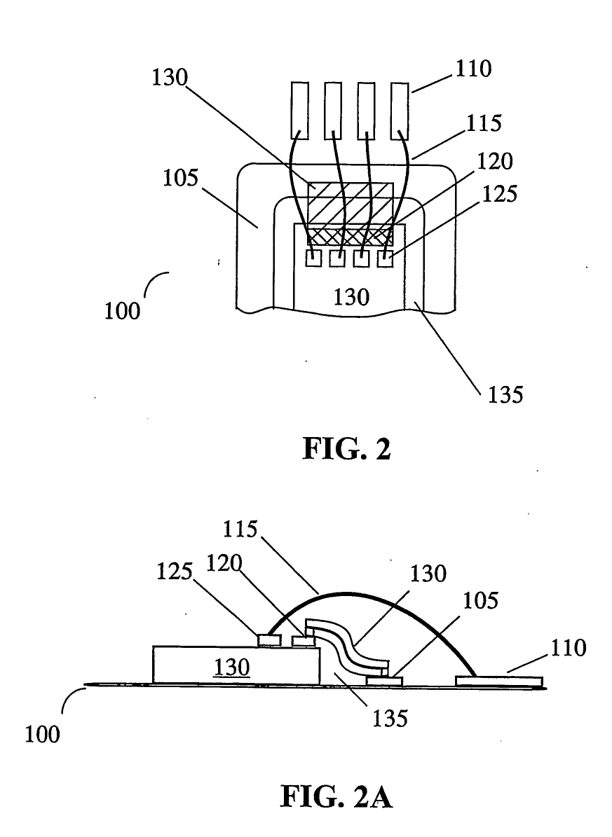

FIG. 2 is a top view of an embodiment according to the present invention;

FIG. 2A is a side view of the embodiment depicted in FIG. 2;

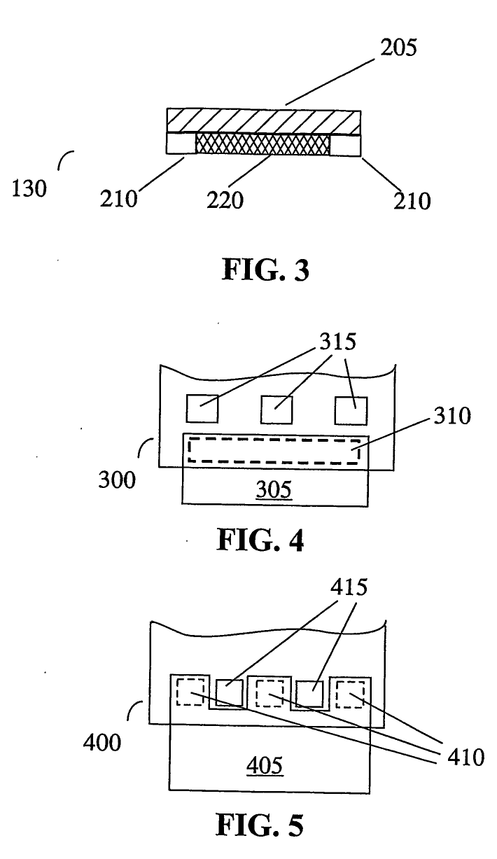

FIG. 3 is a side view of the power/ground strap depicted in FIG. 2A comprised of a composite of materials;

FIG. 4 is a detailed top view of a power/ground strap and how it is attached to an IC device die power/ground pad in accordance with the present invention;

FIG. 5 depicts another embodiment of a power/ground strap and how it is attached to bond pads of an IC die in accordance with the present invention; and

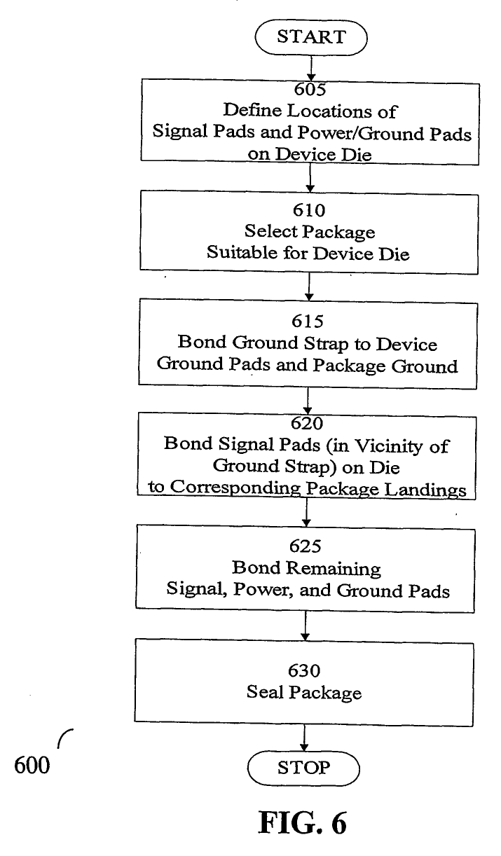

FIG. 6 is a flow chart of packaging a device die in accordance with an example embodiment of the present invention.

The present invention is advantageous in reducing the impedance of the paths connecting the power or ground of the device and the BGA package. Furthermore, the present invention can control the impedance of the signal bond wires by placing a ground strap at a predetermined distance from the signal bond wires. As shown in FIG. 1, a graph of Bond Wire Height over the Ground Strap v. Impedance depicts the relationship. The plot assumes a 25 μm diameter wire and a bonding pitch of 50 cm. For the case of a bond wire without a ground strap, the impedance value is equivalent to the value at a height of 500 μm, 138 ohms.

Design requirements would dictate the desired electrical parameters. Impedances of 50, 75, and 100 ohms are often used. For example, to obtain an impedance of about 50 ohms a height of 25 μm is used. For an impedance of 75 ohms, the height of the bond wire with respect to the ground strap is about 50 μm To obtain an impedance of about 100 ohms a height of 125 μm is used.

Referring now to FIGS. 2 and 2A, in an example embodiment according to the present invention, a low impedance power or ground connection is made between a device die and package in close proximity to wire bonds. This lessens the wire bonds' impedance. An example package 100 has a die 140 attached on a platform (not illustrated) within the package cavity 135. The example package may be a BGA-type configuration. For high pin count BGA packages (greater than 200 balls), the present invention provides a way of controlling the impedance especially in a high-speed impedance sensitive application. The technique may be applied to any given device die and high ball count BGA packages to enhance performance. In an example specific design, it may be useful to design ground pads interspersed among signal pads to better accommodate the ground strap.

In a high-speed impedance sensitive application, having the ground strap enables the user to maintain a constant characteristic impedance, for example 100 ohms, throughout the package. Typically, the device output of a die is connected to a bond wire having an impedance of about 138 ohms and a length of about 4 mm, which is then connected to a package trace having an impedance of about 90 ohms and a length of about 10 mm. By using the ground strap in accordance with the present invention and with careful routing one can maintain a constant 100 ohm impedance from the device die to the package ball for the entire 14 mm length.

The lowered inductance of the ground strap improves the signal integrity by reducing the induced noise on the power or ground due to I/O switching current.

A ground ring 105 surrounds the die 140. Bond pads 125 are device signal pads coupled with wire bonds 115 to package pad landings 110. The wire bonds 115 are in close proximity to ground strap 130, which in turn, is attached to a dedicated grounding pad 120 on the device. This dedicated grounding pad may be a single pad or multiple pads depending upon the circuit design and layout. The robustness of the grounding strap 130 enhances the device's ability to handle the transient currents of SSO. The ground strap inductance is about 1.3 nH for a 2 mm strap as compared to 2 nH for a 2 mm bond wire. The ground strap reduces the inductance mostly due to its size in relation to the bond wire.

Referring now to FIG. 3, the grounding strap 130 may be made of any suitable conductive material. In an example embodiment the grounding strap 130 is comprised of copper. The grounding strap 130 is a composite of materials. On one implementation of the grounding strap 130, on the top surface, there is a copper layer 205 of sufficient thickness for a given application. To facilitate bonding, the copper layer 205 has gold 210 attached at each end so as to facilitate the attachment of the strap to the device's grounding bonding pad 125 and the ground ring 105. An insulating material, such as a non-conductive metal oxide may be added to form a layer 220. This layer 220 may be added to lessen the likelihood of forming accidental short-circuits during the wire bonding process. Other dielectrics may include polyimide, polyimide/polyamide, solder mask, PTFE, TEFLON™, or any other flexible dielectric suitable for printed circuit boards (PCBs).

Referring now to FIG. 4, the grounding pad on the device may be configured in many ways. The criteria used in a given configuration, depend upon the design and layout rules and the degree of grounding strapping required. The arrangement 300 depicts a ground strap 305 bonded to a specialized ground pad 310 (shown in dashed lines). Bonding pads 315 are located in close proximity. Bond wires attached thereon will have reduced impedance owing to the contribution made by the ground strap 305.

Referring to FIG. 5, in another embodiment according to the present invention, the ground strap may include extending protrusions such that signal pads are situated between grounding pads bonded to the package's grounding ring. Arrangement 400 comprises signal pads 415 located between grounding pads 410, shown in dashed lines. The grounding strap 405 has fingers for bonding the strap to the ground pads 410.

FIG. 6 shows a flow chart where the above embodiments may be applied to a given device die having a high pin count and being packaged in a correspondingly high ball/pin count package. In an example embodiment, a series of steps 600 may be followed to implement the present invention on a device die and package. The designer defines the location of the signal and power/ground pads on the device at 605. Up front design work would focus on minimizing the incidence of noise on the device while increasing the performance of the device. A suitable package for the device and application is selected at 610. Steps 605 and 610 often occur before any actual design is rendered in silicon. However, the present invention may be applied to any device and package combination. Having defined the device die pad layout and package, the bond ground strap is connected to the device ground pads and to the package ground at 615. Depending upon the type of package, these may be bonding pads or a ground ring that surrounds the device die, as in the case of FIG. 2. In addition, multiple ground straps may be used in a device/package configuration. After bonding the ground strap the device signal pads in the vicinity of the ground strap may be wire bonded to the corresponding package landings at 620. Remaining signal, power, and ground pads are bonded at 625. After bonding is complete, the package is sealed at 630.

While the present invention has been described with reference to several particular example embodiments, those skilled in the art will recognize that many changes may be made thereto without departing from the spirit and scope of the present invention, which is set forth in the following claims.

1. An integrated circuit device comprising: an integrated circuit having a plurality of grounding pads, signal pads, and power pads; and a package for mounting the integrated circuit; wherein the package comprises, a grounding ring surrounding the integrated circuit; and a grounding strap coupling the grounding ring (105) to the grounding pads of the integrated circuit.

2. The integrated circuit device of claim 1 wherein the package further comprises a plurality of pad landings.

3. The integrated circuit device of claim 2 wherein the signal pads of the integrated circuit are coupled to the pad landings with bond wires.

4. The integrated circuit device of claim 3 wherein the bond wires are in close proximity to, but not touching, the grounding strap.

5. The integrated circuit device of claim 1 wherein the grounding strap comprises copper conductors.

6. The integrated circuit device of claim 1 wherein the grounding strap comprises gold conductors.

7. The integrated circuit device of claim 1 wherein the grounding strap comprises silver conductors.

8. The integrated circuit device of claim 1 wherein the grounding strap comprises aluminum conductors.

9. The integrated circuit device of claim 1 wherein the grounding strap comprises conductors of a highly conductive material selected from: copper, gold, silver, aluminum and an alloy thereof.

10. The integrated circuit device of claim 1 wherein the grounding strap further comprises, a first conducting material providing a first conductor and having a first length and a first cross-section, the first conductor having a top surface and a bottom surface.

11. The integrated circuit device of claim 10 wherein the grounding strap further comprises, a dielectric material having a second cross-section and a second length, the second cross-section being about equal to the first cross-section of the first conductor, the second length shorter than the first length, the dielectric material being attached to the first conductor at about the midpoint of the first length, leaving a first gap and a second gap of the first conductor exposed.

12. The integrated circuit device of claim 11 wherein the grounding strap further comprises, a second conducting material applied to the first conductor at the first gap and the second gap, the second conducting material applied so that the second conducting material is substantially flush with the dielectric material; and wherein the grounding strap is formed in a manner so that the first gap couples to the grounding ring and the second gap couples to the grounding pads of the integrated circuit.

13. The integrated circuit device of claim 2 wherein the grounding strap further comprises a first conducting material providing a first conductor and having a first length and a first cross-section, the first conductor having a top surface and a bottom surface.

14. The integrated circuit device of claim 13 wherein the grounding strap further comprises, a dielectric material having a second cross-section and a second length, the second cross-section being about equal to the first cross-section of the first conductor, the second length shorter than the first length, the dielectric material being attached to the first conductor at about the midpoint of the first length, leaving a first gap and a second gap of the first conductor exposed.

15. The integrated circuit device of claim 14 wherein the grounding strap further comprises, a second conducting material applied to the first conductor at the first gap and the second gap, the second conducting material applied so that the second conducting material is substantially flush with the dielectric material; and wherein the grounding strap is formed in a manner so that the first gap couples to the grounding ring and the second gap couples to the grounding pads of the integrated circuit.

16. The integrated circuit device of claim 4, wherein the dielectric material is selected from at least one of the following: polyimide, polyamide, soldermask, PTFE, and TEFLON™.

17. The integrated circuit device of claim 1 wherein in the integrated circuit, the plurality of signal pads and plurality of grounding pads are arranged so that a signal pad is adjacent to a grounding pad.

18. A method for controlling impedance of bond wires in packaging a semiconductor device die in a ball grid array package, the method comprising: defining locations of signal and power/ground pads on the device die; selecting a suitable package having a ground for the device die; bonding a ground strap to the device die ground pads and the package ground, coupling the device die ground pads to the package ground; bonding signal pads, in the vicinity of the ground strap, of the device die to package landings; bonding remaining signal, power and ground pads of the device die to package landings; and sealing the package.
